(19) United States
(12) Patent Application Publication
(10) Pub. No.: US 2025/0050375 A1
(43) Pub. Date: Feb. 13, 2025

(54) METHOD FOR COATING GRAPHITE HEAT DISSIPATION SHEET FOR DISPLAY PANEL

(71) Applicant: INDONG ADVANCED MATERIALS, INC., Cheonan-si (KR)

(72) Inventors: Hyun Ho LEE, Hwaseong-si (KR); Song Yong YUN, Pohang-si (KR); Sin Woo NAM, Jincheon-gun (KR)

(21) Appl. No.: 18/928,211

(22) Filed: Oct. 28, 2024

Related U.S. Application Data
(63) Continuation of application No. PCT/KR2023/002833, filed on Mar. 2, 2023.

(30) Foreign Application Priority Data
Apr. 28, 2022 (KR) 10-2022-0052723

(51) Int. Cl. B05D 1/06; C01B 32/21; C09D 5/03; C09D 7/61; C09D 163/04

(52) U.S. Cl. CPC B05D 1/06; C01B 32/21; C09D 5/035; C09D 7/61; C09D 163/04

(57) ABSTRACT

The present invention relates to a method for coating a graphite heat dissipation sheet, comprising a step of coating the surface of a graphite sheet with a powder paint through electrostatic spraying, thereby forming a coating layer on the surface of graphite, wherein the powder paint comprises: 80-90 parts by weight of an epoxy resin consisting of 30-40 wt % of an o-cresol novolac epoxy resin with a softening point of 70-90° C. and 60-70 wt % of a bisphenol A epoxy resin with a softening point of 110-120° C.; 10-30 parts by weight of a polyester resin containing a carboxyl group at the terminal thereof; 0.1-5 parts by weight of a curing accelerator; and 20-30 parts by weight of a layered clay mineral.

### TECHNICAL FIELD

The present disclosure relates to a method for coating a graphite heat dissipation sheet for a display panel. More particularly, the present disclosure relates to a method for coating a graphite heat dissipation sheet, the method being configured such that a coating layer is formed by using a coating agent by improving a conventional method in which a film is laminated on a surface of graphite, thereby being capable of increasing the heat dissipation performance of the display panel

### BACKGROUND ART

Due to the characteristics of a graphite material having a low hardness, there is a problem that dust or scattering of the graphite material occurs when a heat dissipation sheet formed of the graphite material such as expanded graphite is processed into a sheet or a structure, and there is a problem that the mechanical properties and insulation properties of the heat dissipation sheet are low. In order to solve these problems, in a process of manufacturing a graphite heat dissipation sheet, a protective sheet is laminated on the surface of the heat dissipation sheet so as to secure the mechanical properties while preventing the occurrence of dust or scattering.

The applicant has developed a method of laminating a protective sheet on a graphite heat dissipation sheet through Korean Patent No. 10-2148670. Recently, in order to solve the problem of generation of heat due to miniaturization of an electronic device to which a heat dissipation sheet is applied, since a product development has been performed with a trend of mounting a heat dissipation sheet of the same size as a mounting area of the electronic device when the graphite heat dissipation sheet is mounted, a method of laminating a protective sheet without a bezel as described in the related art is useful.

However, in order to realize a bezel-less structure in which a bezel does not exist, the heat dissipation sheet is required to be manufactured through a complex process such as cutting such that a step difference of less than 1 mm occurs inside compared to an outer size of the heat dissipation sheet, laminating lower and upper protective sheets, and padding the protective sheet around the circumference of the heat dissipation sheet. Therefore, mass production is difficult to be realized, and there is a problem in terms of economic feasibility of the process.

In addition, as a technology for coating a graphite surface, a technology for forming a coating protective film formed of a polydimethylsiloxane resin having an insulation property is disclosed in Korean Patent No. 10-1430235. This is a technology of performing coating in an electrostatic manner by using a coating solution in which 30 to 90 parts by weight of a graphene and graphite mixture, and 2 to 10 parts by weight of a silicone dispersant are mixed, relative to 1000 parts by weight of solvent. In the coating method using the liquid coating agent, a liquid component permeates into the graphite surface, so that there is a problem that complete drying is difficult to be performed in the process.

Through Korean Patent No. 10-2333315, the applicant has developed a heat dissipation sheet coating method for forming a coating layer by using a coating agent by improving the conventional method in which the film is laminated on the surface of graphite. When such a coating method is applied, a coating layer may be formed on the surface of graphite in a non-contact coating manner by using a powder paint, so that the efficiency of the coating process may be increased.

In a display that implements high resolution such as a QD display that is recently developed, there is a limitation in reducing the thickness due to a heat generation. In order to solve this problem, it is necessary to improve a heat dissipation structure or a heat dissipation sheet that is to be applied to the heat dissipation structure. However, when the graphite heat dissipation sheet in which the coating layer is formed is applied to a display panel, there is a problem that the coating layer of the heat dissipation sheet is deteriorated as the amount of heat generated increases, and there is a problem that the lifespan of the graphite heat dissipation sheet is reduced.

### DISCLOSURE

### Technical Problem

Accordingly, the present disclosure has been made keeping in mind the above problems occurring in the related art, and an objective of the present disclosure is to provide a method for coating a graphite heat dissipation sheet, the method being improved such that the graphite heat dissipation sheet has the performance suitable for being applied to a display panel by increasing the heat resistance of a coating layer which is formed on a surface of graphite in a non-contact coating manner by using a powder paint.

### Technical Solution

In order to achieve the objective of the present disclosure, according to the present disclosure, there is provided a method for coating a graphite heat dissipation sheet, the method including forming a coating layer on a surface of graphite by coating a surface of a graphite sheet with a powder paint through electrostatic spraying, wherein the powder paint includes 80 to 90 parts by weight of an epoxy resin consisting of 30 wt % to 40 wt % of an ortho-cresol novolac epoxy resin with a softening point of 70 degrees Celsius to 90 degrees Celsius and 60 wt % to 70 wt % of a bisphenol A epoxy resin with a softening point of 110 degrees Celsius to 120 degrees Celsius, 10 to 30 parts by weight of a polyester resin containing a carboxyl group at a terminal thereof, 0.1 to 5 parts by weight of a curing accelerator, and 20 to 30 parts by weight of a layered clay mineral.

At this time, the graphite sheet may be formed of any one or a combination of natural graphite, artificial graphite, expanded graphite, graphene, and kish graphite.

In addition, in the forming of the coating layer, a front surface, a rear surface, and a border of the graphite sheet are coated simultaneously.

### Advantageous Effects

When the method for coating the graphite heat dissipation sheet according to the present disclosure is applied, the coating layer may be formed on the surface of graphite by using the power paint in the non-contact coating manner.

In addition, since the heat resistance of the coating layer formed on the surface of graphite is increased, the performance suitable for application to a display panel may be realized.

### MODE FOR INVENTION

Hereinafter, the present disclosure will be described in more detail. Prior to the description, it should be understood that the terms used in the specification and the appended claims should not be construed as limited to general and dictionary meanings, but interpreted on the basis of the meanings and concepts corresponding to technical aspects of the present disclosure on the basis of the principle that the inventor is allowed to define terms appropriately for the best explanation.

A method for coating a graphite heat dissipation sheet of the present disclosure includes coating a surface of a graphite sheet with a powder paint through electrostatic spraying, thereby forming a coating layer on a surface of graphite.

The coating method is a method disclosed in Korean Patent No. 10-2333315 developed by the present applicant, and the present disclosure is intended to improve the coating method so that physical properties suitable for application to a display are secured.

Recently, an 8K UHD display using a QD type or an OLED type has been developed so as to realize high resolution. In order to develop a display that realizes such high resolution, it is necessary to solve not only a yield problem but also a heat generation problem. To this end, a technology for increasing the heat dissipation efficiency by forming a coating layer on a surface of a graphite heat dissipation sheet has been developed.

As a process for coating a surface of the heat dissipation sheet, a coating method in which a paint is coated on upper and lower surfaces of the heat dissipation sheet and the heat dissipation sheet is dried and cured so as to manufacture the coated heat dissipation sheet and then the coated heat dissipation sheet is cut, and a coating method of performing a sequential process in which the heat dissipation sheet is cut and an upper surface of the cut heat dissipation sheet is coated with a paint and the upper surface of the cut heat dissipation sheet is dried and cured and then a lower surface of the cut heat dissipation sheet is coated with the paint and the lower surface of the cut heat dissipation sheet is dried and cured are applied. However, in the method in which the paint is applied on the upper and lower surfaces and then drying and curing are performed, coating is capable of being performed in a continuous process while a heat dissipation sheet is moved. However, there is a problem that a heat dissipation sheet with a desired quality is not manufactured since a coating layer is not uniformly formed. Furthermore, when a heat dissipation sheet is cut and then coating is performed sequentially in an order of an upper surface, a lower surface, and a border of the heat dissipation sheet, the thickness deviation of a coating layer may be reduced, but a process becomes complicated and the economic feasibility is reduced, so that is difficult to apply the method to an actual manufacturing process.

In order to solve the problems of the process, the applicant performed a process of coating a graphite heat dissipation sheet in an electrostatic spray painting manner by using a powder paint instead of a liquid coating agent that is generally used. In the coating process, since there is an advantage that a front surface, a rear surface, and a border of the heat dissipation sheet are capable of being coated at the same time, the number of coating processes may be reduced, and the process efficiency may be increased accordingly. In addition, the problem of non-uniform drying that occurred when the liquid coating agent is used may be solved.

Although the painting method using a powder paint has this advantage, coating a graphite surface by using a powder paint that is generally used is very difficult to be performed. This is due to the fact that there is no reaction site on the graphite surface on which paint particles are capable of being adsorbed, and is due to material characteristics of graphite, such as pores between graphite particles, the surface hydrophobicity, and so on.

Particularly, it was found that when the powder paint that is generally used is applied to a display with significantly increased heat generation, such as an 8K UHD display, a problem that the adhesiveness of the heat dissipation sheet and the heat dissipation efficiency are reduced.

Therefore, in order to improve the powder paint disclosed in Korean Patent No. 10-2333315, the applicant intends to improve the physical properties of the powder paint by changing a resin, a heat dissipation material, and so on that constitute the powder paint.

The powder paint of the present disclosure includes 80 to 90 parts by weight of an epoxy resin consisting of 30 wt % to 40 wt % of an ortho-cresol novolac epoxy resin with a softening point of 70 degrees Celsius to 90 degrees Celsius and 60 wt % to 70 wt % of a bisphenol A epoxy resin with a softening point of 110 degrees Celsius to 120 degrees Celsius, 10 to 30 parts by weight of a polyester resin containing a carboxyl group at a terminal thereof, 0.1 to 5 parts by weight of a curing accelerator, and 20 to 30 parts by weight of a layered clay mineral.

In the powder paint that the applicant has previously developed, an epoxy resin widely used in an epoxy powder paint, which particularly is a bisphenol A epoxy resin having excellent chemical resistance, adhesiveness, and high-temperature characteristics, was used. The epoxy resin causes partial delamination of the layered clay mineral used as inorganic filler to the powder paint. In order to prevent the partial delamination of the layered clay mineral, a neutral surfactant that does not react with interlayer ions of the layered clay mineral was added to prevent layer delamination. Nevertheless, it was found that when the epoxy resin is exposed to a continuous heat-generating environment, layer delamination occurs, so that the heat dissipation efficiency is reduced. Particularly, in applications such as a high resolution display that is exposed to a high temperature environment for a long time, adhesiveness may also be reduced.

Generally, it is known that the physical properties of an ortho-cresol novolac epoxy resin used as a semiconductor molding material are changed according to the softening point. For example, when the softening point is increased, there is no change in physical properties such as the flexural elasticity rate, the coefficient of thermal expansion in a glassy state, and the thermal conductivity, but the glass transition temperature increases and the spiral flow decreases. This is presumed to be due to the increase in crosslinking density under a condition in which the softening point increases, i.e., a condition in which the molecular weight increases. Therefore, it was found that when the ortho-cresol novolac epoxy resin having an appropriate softening point is used, the problem of the occurrence of layer delamination due to the insertion of alkyl chains between the layers may be reduced, and the durability may be enhanced so that adhesiveness is maintained even when the ortho-cresol novolac epoxy resin is exposed to the high-temperature environment.

In addition, it was found that when the bisphenol A epoxy resin having a relatively high softening point is mixed to the ortho-cresol novolac epoxy resin in an appropriate ratio, the problem of reducing the spiral flow may be solved, so that the uniformity and the durability of a coating film formed by a coating process may be secured.

Therefore, in the present disclosure, 30 wt % to 40 wt % of an ortho-cresol novolac epoxy resin with a softening point of 70 degrees Celsius to 90 degrees Celsius and 60 wt % to 70 wt % of a bisphenol A epoxy resin with a softening point of 110 degrees Celsius to 120 degrees Celsius are used as the epoxy resin. The range of softening points and content ratios were optimized through experimentation, and it was found that if the epoxy resin content deviates from this range, coating defects occur in the coating process using the powder paint or the durability of a coating layer decreases. Particularly, it was found that a significant reduction in heat dissipation performance over time occurs if the epoxy resin content deviates from this range.

Additionally, it is preferable that an epoxy resin with an epoxy equivalent weight of 190 g/eq to 220 g/eq is used as the bisphenol A epoxy resin. This is because when the epoxy equivalent weight is too low, there is a problem in the storage stability and chipping resistance of the powder paint, and when the epoxy equivalent weight is too high, there is a problem in the appearance and the productivity of the coating layer. In addition, in order to increase the chipping resistance and the productivity after performing powder paint coating, it is preferable that a bisphenol A novolac epoxy resin containing a novolac group.

In the powder paint, the epoxy resin is contained in the range of 80 to 90 parts by weight. When the epoxy resin content is too low, there is a problem that the adhesiveness to the graphite surface is decreased. Furthermore, when the epoxy resin content is too high, there is a problem that the curing speed, the edge covering force, and so on are decreased. Compared to the conventional powder paint, a larger amount of epoxy resin is used, which is because the adhesiveness is capable of being increased since the delamination of the layered clay mineral does not occur even if the larger amount of epoxy resin is contained.

In addition, the powder paint of the present disclosure includes the polyester resin containing the carboxyl group at the terminal thereof as a curing agent. The carboxyl group positioned at the terminal of the polyester resin promotes a ring-opening reaction of epoxy in the presence of a base catalyst, thereby accelerating the curing of the epoxy resin. It is preferable that the polyester resin containing the carboxyl group at the terminal thereof is included in the range of 10 to 30 parts by weight. When the curing agent content is too low, uncured areas occur. Furthermore, when the curing agent content is too high, the physical properties of the coating layer decrease, which may deteriorate the physical properties of the graphite heat dissipation sheet. The polyester resin containing the carboxyl group at the terminal thereof may be manufactured by reacting a carboxylic acid with 1 to 3 carbon atoms with a polyester resin in the presence of a base catalyst.

In addition, the powder paint contains the curing accelerator. As the curing accelerator, a compound containing a functional group that is capable of promoting curing at a terminal group. The curing accelerator may be selected from an amine-based compound, an imidazole-based compound, benzoyl peroxide, or a mixture thereof. The imidazole-based curing accelerator may be 2-methylimidazole, and the amine-based curing accelerator may be an amine adduct.

The curing accelerator is included in the range of 0.1 to 5 parts by weight. When the curing accelerator content is too low, there is a problem that the curing time is increased. Furthermore, when the curing accelerator content is too high, there is a problem that the curing time is decreased but the appearance of the coating layer is deteriorated and the surface non-uniformity is increased.

In addition, as described above, the layered clay mineral is used as the inorganic filler in the present disclosure.

The layered clay mineral is also used in Korean Patent No. 10-2333315. As described above, in the present disclosure, the ortho-cresol novolac epoxy resin is used so as to prevent the delamination of the layered clay mineral.

The stratified clay mineral may be halloysite, kaolinite, smectite, montmorillonite, hectorite, saponite, or a vermiculite having a layered silicate or silica-alumina clay mineral. Since the layered clay mineral has a wide surface area of at least 800 m² on average per gram. Furthermore, the layered clay mineral has a structure in which several tens to several hundreds of ultra-thin sheets with 1 nm in thickness and 30 nm to 1,000 nm in length are stacked. Therefore, when this layered structure is disrupted and each nano sheet is homogeneously dispersed into a polymer matrix as a type of nano filler, it has been reported that, unlike conventional polymer composites where inorganic fillers are introduced into a polymer matrix in an aggregated state with sizes exceeding several micrometers, even with a very small amount of filler, along with an increase in mechanical properties several times compared to the properties of polymer resins, various changes in physical properties such as heat resistance, electrical properties, and gas barrier properties may be realized.

Particularly, when the layered clay mineral is processed as an interlayer insertion material, the interlayer distance is capable of being adjusted. Furthermore, it was found that the layered clay mineral is suitable for being used as a filler due to the simplicity of the synthesis process of the layered clay mineral. In graphite, the interlayer distance is about 0.7 nm. Therefore, due to the characteristics of the layered clay mineral having the interlayer distance of 0.9 nm to 1.0 nm in a contraction state, when the coating layer is formed adjacent to graphite, excellent heat dissipation characteristics may be realized without adjusting the interlayer distance.

The interlayer distance of the layered clay mineral is different according to a crystal structure. For example, the interlayer distance of kaolinite measured by the X-ray diffraction method is about 7 Å, and smectite having the widest interlayer distance has the interlayer distance of 10 Å to 18 Å. In addition, through DTA analysis, it was evaluated that the phase transition temperature is at least 600 degrees Celsius, so that the layered clay mineral is evaluated as a material capable of showing high heat resistance characteristics.

As a result of manufacturing the powder paint by using various layered clay minerals, it has been confirmed that the powder paint has an optimal effect when halloysite is used. Halloysite is a layered clay mineral composed of aluminosilicate (Al₂Si₂O₅(OH)₄) with a structure similar to kaolinite. Halloysite has a characteristic structure in which water molecules are present between layers thereof, so that the interlayer distance measured by the X-ray diffraction method is 7 Å in a dehydrated state, whereas the interlayer distance is changed to 10 Å in a hydrated state. Due to these characteristics, the possibility of alkyl chains being inserted into the layers when a polymer is mixed may be suppressed. Particularly, it has been evaluated that the compatibility of halloysite with the epoxy resin of the present disclosure is excellent. For this reason, unlike the powder paint in the related art, there is no need to separately mix the neutral surfactant in order to suppress the layer delamination.

The layered clay mineral is used in a range of 20 to 30 parts by weight. by increasing the content of the layered clay mineral compared to that of the related art, the heat dissipation effect of the powder paint may be further increased. However, when the content of the layered clay mineral is too small, sagging of the coating layer occurs, a concealment force is reduced, and the heat dissipation performance may be reduced. Furthermore, when the content of the layered clay mineral is too high, the relative content of the resin is reduced, and the physical properties of the coating layer may be deteriorated, so that it is preferable that the content range of the layered clay mineral described above is used.

In addition, as required, ordinary additives such as a bubble prevention agent, a gloss control agent, a dispersing agent, and so on may be added. When the additive is used, it is preferable that the additive is used in a range of 0.1 to 5 parts by weight. When the content of the additive is too low, it is not effective because there is no difference from when the additive is not used. When the content of the additive is too high, there is no increase in the effect due to the additive mixing, so that it is uneconomical, and may cause a problem in the appearance of the coating layer in some cases.

When the powder paint as described above is used, the front surface, the rear surface, and the border of the graphite sheet may be simultaneously coated by using the electrostatic spray painting method. Since the electrostatic spray painting method is a method in which the powder paint is attached to a surface by using an electrostatic force, simultaneous coating on the entire surface of the sheet is capable of being realized.

Specifically, a cutting process in which the graphite sheet is cut to a required size, a painting process in which the cut graphite sheet is mounted on an electrostatic spray painting apparatus and the powder paint is coated on the surface of the graphite sheet, and a process in which the painted graphite sheet is thermally treated so that the powder paint is attached to the surface of the graphite sheet and then cured, are performed, so that the coating layer may be formed on the graphite surface. In a state in which the powder paint is coated on the graphite sheet, the thermal treatment may be performed at a temperature of 50 degrees Celsius to 250 degrees Celsius, preferably at a temperature of 50 degrees Celsius to 150 degrees Celsius, for 30 seconds to 3000 minutes for curing, preferably for 5 minutes to 20 minutes for curing. According to a process condition, the coating layer having a thickness of 2 μm to 300 μm, preferably a thickness of 10 μm to 100 μm, may be formed.

In addition, since the level of physical properties corresponding to the level of physical properties when a conventional protective sheet is laminated is required to be secured, the manufactured graphite sheet may have a flexural rigidity equal to or less than 1.5 inches, a pencil hardness of B or more, and an impact resistance of 5 kg·cm or more.

When the coating method of the present disclosure is applied, the coating layer may be formed on the surface of the graphite heat dissipation sheet that is difficult to be coated, so that it is found that finishing of the graphite heat dissipation sheet is capable of being performed more economically and efficiently compared to that of a conventional method of laminating a protective sheet.

In order to check whether the performance of the heat dissipation sheet is increased when the coating method of the present disclosure is applied, the graphite sheet is manufactured as follows and the physical properties of the graphite sheet is evaluated.

As the graphite sheet, the graphite sheet which is manufactured by Indong Advanced Materials, Inc., and which has the thickness of 500 μm to 920 μm was used. The graphite sheet was fixed and electrostatic spray painting was applied under a constant voltage of 70 kV. At this time, the coating process was performed with a distance of 25 cm between a spray gun and a material to be coated and with a flow rate in a booth being 0.4 m/sec.

The powder paint for performing the coating process is manufactured by mixing the components with the contents ratio as shown in Table 1. In Table 1, the units are parts by weight, and Comparison example 3 was prepared according to an embodiment in Korean Patent No. 10-2333315.

TABLE 1

| | Embodiment | Embodiment | Comparison | Comparison | Comparison |
|---|---|---|---|---|---|
| | 1 | 2 | example 1 | example 2 | example 3 |
| EOCN-1020 | 35 | | | | |
| EOCN-1025 | | 32 | | 50 | |
| EOCN-1027 | | | 32 | | |
| BPA | 65 | 65 | 65 | 45 | 70 |
| C-PE | 20 | 20 | 20 | 20 | 20 |
| 2-MI | 1.5 | 1.5 | 1.5 | 1.5 | 2 |
| halloysite | | | | | |
| hectorite | | | | | 20 |
| poloxamer | | | | | 2 |
| 407 | | | | | |

EOCN-1020: ortho-cresol novolac epoxy resin, softening point 83 degrees Celsius
EOCN-1025: ortho-cresol novolac epoxy resin, softening point 72 degrees Celsius
EOCN-1027: ortho-cresol novolac epoxy resin, softening point 65 degrees Celsius
BPA: bisphenol A novolac epoxy resin, MF-8120, softening point 118 degrees Celsius
C-PE: polyester resin containing a carboxyl group at a terminal thereof
2-MI: 2-methylimidazole

The results of evaluating the physical properties of each graphite sheet are shown in Table 2. In Table 2, the flexural rigidity was measured according to KS M ISO 6860, the pencil hardness was measured according to KS M ISO 1519, and the impact resistance was measured according to KS M ISO 6272-2.

TABLE 2

| | Embodiment | Embodiment | Comparison | Comparison | Comparison |
|---|---|---|---|---|---|
| | 1 | 2 | example 1 | example 2 | example 3 |
| Flexural | 1.1 | 1.0 | 1.3 | 1.2 | 1.2 |
| rigidity (inch) | | | | | |
| Pencil hardness | 2H | 2H | F | F | F |
| Impact | 6 | 7 | 6 | 5 | 6 |
| resistance (kg | | | | | |
| cm) | | | | | |

Looking at the results of Table 2, the graphite sheets according to the embodiments and the comparison examples have excellent flexural rigidity, excellent impact resistance, and excellent durability of the film. This is a result suggesting that the surface stability of the graphite sheet coated by using the powder paint of the present disclosure is increased.

In addition, the thermal diffusivity of the graphite sheet coated by the coating method of the present disclosure was tested. The graphite sheet was cut in a size of 100 mm×10 mm in a width×a length, a double-sided tape was attached to a first surface of an electromagnetic shielding layer, and the graphite sheet was attached to a heating block. Then, the temperature of the heating block was increased to 90±2 degrees Celsius.

After the temperature was increased, the heating block was sealed in a box and a stabilizing process was performed for 10 minutes, and the temperature of the stabilized sample was measured by using an infrared camera. The highest temperature (hot spot) and the lowest temperature (cold spot) of the graphite sheet were secured at the measured temperature, and the difference in temperature (ΔT) between the hot spot and the cold spot was evaluated as the thermal diffusivity. That is, a lower ΔT may be evaluated as reflecting better thermal dissipation efficiency.

In addition, considering a mounting process of the graphite sheet, multiple through-holes (4Φ hole) were formed in the graphite sheet by performing a punching process, and the peel strength of the through-holes was measured by performing a 180° Peel Test (JIS C 6741 standard).

The results of evaluating each graphite sheet are shown in Table 3.

TABLE 3

| | Embodiment | Embodiment | Comparison | Comparison | Comparison |
|---|---|---|---|---|---|
| | 1 | 2 | example 1 | example 2 | example 3 |
| Thermal | 20.62 | 20.85 | 26.12 | 22.35 | 20.78 |
| diffusivity | | | | | |
| (Δ T) | | | | | |
| Peel strength | 338 | 336 | 292 | 309 | 312 |
| (gf/hole) | | | | | |

Looking at the results of Table 3, in the graphite sheets of Embodiment 1 and Embodiment 2, the thermal diffusivity is excellent and the peel strength of the through-hole is relatively high, so that the durability of the coating layer formed on the surface of the graphite sheet and the degree of improvement in the heat dissipation effect due to the coating layer were evaluated as excellent. Particularly, the thermal diffusivity and the peel strength are higher than that of Comparison example 3 in which the powder paint of the related art is applied, so that the powder paint of the present disclosure has the physical properties suitable for being applied to a display with significantly increased heat generation, such as an 8K UHD display.

It will be apparent that the scope of the present disclosure is not limited to the embodiments described above and defined by those disclosed in the appended claims, and those skilled in the art can make various modification and changes within the scope disclosed in the appended claims.

1. A method for coating a graphite heat dissipation sheet, the method comprising forming a coating layer on a surface of graphite by coating a surface of a graphite sheet with a powder paint through electrostatic spraying,
wherein the powder paint comprises 80 to 90 parts by weight of an epoxy resin consisting of 30 wt % to 40 wt % of an ortho-cresol novolac epoxy resin with a softening point of 70 degrees Celsius to 90 degrees Celsius and 60 wt % to 70 wt % of a bisphenol A epoxy resin with a softening point of 110 degrees Celsius to 120 degrees Celsius, 10 to 30 parts by weight of a polyester resin containing a carboxyl group at a terminal thereof, 0.1 to 5 parts by weight of a curing accelerator, and 20 to 30 parts by weight of a layered clay mineral.

2. The method of claim 1, wherein the graphite sheet is formed of any one or a combination of natural graphite, artificial graphite, expanded graphite, graphene, and kish graphite.

3. The method of claim 1, wherein, in the forming of the coating layer, a front surface, a rear surface, and a border of the graphite sheet are coated simultaneously.
